(19) United States
(12) Patent Application Publication
(10) Pub. No.: US 2026/0190667 A1
(43) Pub. Date: Jul. 2, 2026

(54) LIGHT EMITTING DISPLAY DEVICE

(71) Applicant: LG Display Co., Ltd., Seoul (KR)

(72) Inventors: HeeJung YANG, Paju-si (KR); MinJoo KIM, Paju-si (KR); YoungWook LEE, Paju-si (KR); Jungmin KIM, Paju-si (KR); Hoseung LEE, Paju-si (KR)

(73) Assignee: LG Display Co., Ltd., Seoul (KR)

(21) Appl. No.: 19/394,708

(22) Filed: Nov. 19, 2025

(30) Foreign Application Priority Data
Dec. 30, 2024 (KR) 10-2024-0201469

(51) Int. Cl. H10K 59/124; G09G 3/3233

(52) U.S. Cl. CPC H10K 59/124; G09G 3/3233; G09G 2300/0465; G09G 2300/0842; G09G 2330/021

(57) ABSTRACT

A light emitting display device is discussed. The light emitting display device includes a substrate having a first area and a second area, a driving element layer on the substrate, a light emitting element layer including a planarization layer on the driving element layer, and a plurality of light emitting diodes on the planarization layer. The planarization layer includes an uneven structure disposed on the second area. Each of the plurality of light emitting diodes includes a first electrode, an emission layer and a second electrode. The first electrode of at least one of the plurality of light emitting diodes has an uneven surface corresponding to the uneven structure of the planarization layer. The uneven structure of the planarization layer includes a protruding structure.

### CROSS-REFERENCE TO RELATED APPLICATIONS

This application claims priority to Korean Patent Application No. 10-2024-0201469, filed in the Republic of Korea on Dec. 30, 2024, which is hereby incorporated by reference as if fully set forth herein.

### BACKGROUND

### Field of the Invention

The present disclosure relates to a light emitting display device.

### Discussion of the Related Art

Among the display device, a light emitting display device can have high aperture ratios so that it can provide excellent display quality with a high luminance of power consumption per unit. In particular, a light emitting display device can have a common electrode made of a transparent conductive material. For the light emitting display device having a large diagonal area, it is needed to have a low electric resistance of the common electrode so that there is no difference in brightness across the entire area.

Particularly, in an ultra-high-density resolution display device having a pixel density of 4K (ppi: pixel per inch) or more, since the size of the pixel is very small, the structural improvement for improving light efficiency is needed to provide a brighter and clearer image quality with the same power consumption.

### SUMMARY OF THE DISCLOSURE

One purpose of the present disclosure, as for solving or addressing the problems described above and other limitations associated with the related art, is to provide a light emitting display device having a high luminance of power consumption per unit.

One or more example embodiments of the present disclosure can be directed to providing a light emitting display device capable of low power driving with a higher luminance with the same power consumption by including a micro mirror structure (or mirror structure) having a structure capable of improving light efficiency.

One or more example embodiments of the present disclosure can be directed to provide a light emitting display device which provides uniform brightness and image information regardless of viewing direction by having a concave structure for improving front luminance (or brightness) and/or a convex structure for enhancing viewing angle luminance. Here, the frontal luminance is a luminance of light detected at a front direction. The viewing angle luminance is a luminance of light detected at a lateral viewing angle direction, which is a direction spread in a fan-shaped from the front direction.

In order to solve or address the above-described technical problem and other limitations, one embodiment of the present disclosure provides a light emitting display device, comprising: a substrate including a first area and a second area; a driving element layer on the substrate; a light emitting element layer including a planarization layer on the driving element layer and a plurality of light emitting diodes on the planarization layer, wherein the planarization layer includes an uneven structure disposed on the second area, wherein each of the plurality of light emitting diodes includes a first electrode, an emission layer and a second electrode, wherein the first electrode of at least one of the plurality of light emitting diodes has an uneven surface corresponding to the uneven structure of the planarization layer, and wherein the uneven structure of the planarization layer includes a protruding structure.

In addition, another embodiment of the present disclosure provides a light emitting display device, comprising: a substrate; a driving element layer on the substrate; and a light emitting element layer on the driving element layer and including a plurality of light emitting diodes, wherein each of the plurality of light emitting diodes includes a first electrode, an emission layer and a second electrode, and wherein among the plurality of light emitting diodes, a surface area of the emission layer of a first light emitting diode of a first subpixel is larger than a surface area of the emission layer of a second light emitting diode of a second subpixel.

The light emitting display device according to aspects of the present disclosure can improve light efficiency while the pixel area is the same, by forming a concave and/or convex mirrors structure in the first electrode (e.g., the anode electrode). Even in an ultra-high density resolution display device having very small size of the emission area, a higher luminance can be provided with the same power consumption. Accordingly, the low power driving can be implemented.

The light emitting display device according to aspects of the present disclosure can have a structure that forms a concave mirror (a concave micro-mirror) structure in the emission layer to converge a light in the front direction, or a structure that forms a convex mirror (a convex micro-mirror) structure in the first electrode to diffuse light on the viewing angle direction. Therefore, it is possible to provide an image having a uniform luminance distribution regardless of the position from which the display device is observed. As a result, it is possible to provide high-quality image information without image distortion regardless of the observation location.

In addition to the features and advantages of the present disclosure mentioned above, other features and advantages of the present disclosure are described below, or can be clearly understood by those skilled in the art from such descriptions and explanations.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plane view illustrating a schematic structure of a light emitting display device according to an embodiment of the present disclosure.

FIG. 2 is a circuit diagram illustrating a structure of one pixel disposed in a light emitting display device according to an embodiment of the present disclosure.

FIG. 3 is an enlarged plan view illustrating, as an example, a structure of three pixels sequentially disposed in the light emitting display device according to an embodiment of the present disclosure.

FIG. 4 is a cross-sectional view, cutting along line I-I′ in FIG. 3, for illustrating a structure of one pixel in a light emitting display device according to an embodiment of the present disclosure.

FIG. 5 is a cross-sectional view, enlarging the dotted box ‘X’ of FIG. 4, for illustrating a structure of a light emitting display device according to a first embodiment of the present disclosure.

FIG. 6 is a cross-sectional view, enlarging the dotted box ‘X’ of FIG. 4, for illustrating a structure of a light emitting display device according to a second embodiment of the present disclosure.

FIG. 7 is a cross-sectional view, enlarging the dotted box ‘X’ of FIG. 4, for illustrating a structure of a light emitting display device according to a third embodiment of the present disclosure.

FIG. 8 is a side view for illustrating a structure of a light emitting display device having a flat portion and a curved portion according to a fourth embodiment of the present disclosure.

FIG. 9 is a cross-sectional view, enlarging the dotted box ‘X’ of FIG. 4, for illustrating a structure of a light emitting diode disposed in a flat portion in a light emitting display device according to the fourth embodiment of the present disclosure.

FIG. 10 is a cross-sectional view, enlarging the dotted box ‘X’ of FIG. 4, for illustrating a structure of a light emitting diode disposed in a first curved portion in a light emitting display device according to the fourth embodiment of the present disclosure.

FIG. 11 is a cross-sectional view, enlarging the dotted box ‘X’ of FIG. 4, for illustrating a structure of a light emitting diode disposed in a second curved portion in a light emitting display device according to the fourth embodiment of the present disclosure.

FIG. 12 is a side view for illustrating a structure of a light emitting display device having a flat portion and a curved portion according to a fifth embodiment of the present disclosure.

FIG. 13 is an enlarged plan view for illustrating a distribution of convex and concave structures disposed at the light emitting diodes arranged in the first curved portion in the light emitting display device according to the fifth embodiment of the present disclosure.

FIG. 14 is an enlarged cross-sectional view, cutting along line II-II′ of FIG. 13, for illustrating a distribution of convex and concave structures disposed at the light emitting diodes arranged in the first curved portion in the light emitting display device according to the fifth embodiment of the present disclosure.

FIGS. 15A, 15B and 15C are enlarged plan views for illustrating distributions of convex and concave structures disposed at the light emitting diodes arranged in the second curved portion in the light emitting display device according to the fifth embodiment of the present disclosure.

FIG. 16 is a cross-sectional view, cutting along line III-III′ in FIG. 15B, for illustrating a distribution of convex and concave structures disposed at the light emitting diodes arranged in the second curved portion in the light emitting display device according to the fifth embodiment of the present disclosure.

FIG. 17 is an enlarged plan view for illustrating a distribution of convex and concave structures disposed at the light emitting diodes arranged in the third curved portion in the light emitting display device according to the fifth embodiment of the present disclosure.

FIG. 18 is a cross-sectional view, cutting along line IV-IV′ in FIG. 17, for illustrating a distribution of convex and concave structures disposed at the light emitting diodes arranged in the third curved portion in the light emitting display device according to the fifth embodiment of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration can unnecessarily obscure an important point of the present disclosure, a detailed description of such known function or configuration can be omitted.

Reference will now be made in detail to the example embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms such as “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third layer or element can be interposed therebetween. Further, if a first element is described as positioned “on” a second element, it does not necessarily mean that the first element is positioned above the second element in the drawings. The upper part and the lower part of an object concerned can be changed depending on the orientation of the object. Consequently, where a first element is described as positioned “on” a second element, the first element can be positioned “below” the second element or “above” the second element in the drawings or in an actual configuration, depending on the orientation of the object.

In describing a temporal relationship, when the temporal order is described as, for example, “after,” “subsequent,” “next,” or “before,” a case which is not continuous can be included unless a more limiting term, such as “just,” “immediate(ly),” or “direct(ly),” is used.

It will be understood that, although the terms such as “first,” “second,” and the like can be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) can be used. These terms are used merely to distinguish one element from another, and not to define a particular nature, order, sequence, or number of the elements. Where an element is described as being “linked”, “coupled,” or “connected” to another element, that the element can be directly or indirectly “linked”, “coupled,” or “connected” to that the another element unless otherwise specified. It is to be understood that additional element or elements can be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, for example, the first element, the second element, or the third element. Further, the term “can” fully encompasses all the meanings and coverages of the term “may” and vice versa.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, examples of a display apparatus according to embodiments of the present disclosure will be described in detail with reference to the attached drawings. All the components of each display device/apparatus according to all embodiments of the present disclosure are operatively coupled and configured.

Hereinafter, referring to the attached drawings, the present disclosure will be explained. Since a scale of each of elements shown in the accompanying drawings can be different from an actual scale for convenience of description, the present disclosure is not limited to the scale shown in the drawings.

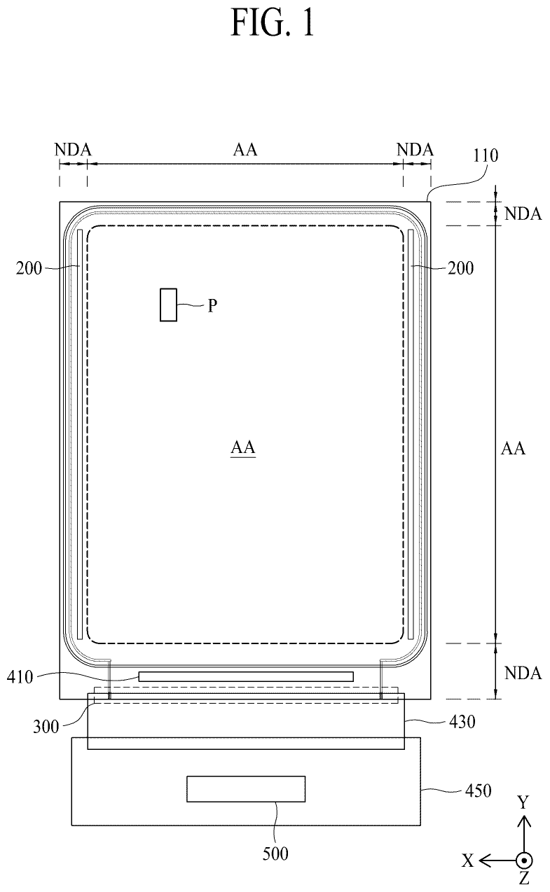

FIG. 1 is a plane view illustrating a schematic structure of a light emitting display device according to an embodiment of the present disclosure. In FIG. 1, an X-axis refers to the direction parallel to the scan line, a Y-axis refers to the direction parallel to the data line, and a Z-axis refers to the height direction of the display device.

Referring to FIG. 1, a light emitting display device comprises a substrate 110, a gate (or scan) driver 200, a pad portion 300, a source driving integrated circuit (IC) 410, a flexible circuit film 430, a circuit board 450, and a timing controller 500.

The substrate 110 can include an electrical insulating material or a flexible material. The substrate 110 can be made of a glass, a metal or a plastic, but it is not limited thereto. When the light emitting display device is a flexible display, the substrate 110 can be made of the flexible material such as plastic. For example, the substrate 110 can include a transparent polyimide material.

The substrate 110 can include a display area AA (or active area) and a non-display area NDA (or non-active area). The display area AA, which is an area for representing the video images, can be defined as the most regions of the substrate 110 including central portion, but it is not limited thereto. In the display area AA, a plurality of pixels P are arrayed in a matrix manner. Further, a plurality of scan lines (or gate lines), a plurality of data lines can be disposed as crossing each other. Each of pixels P can be disposed at the crossing area of the scan line in X-axis and the data line in Y-axis.

Here, the pixel P can represent any one of color among red, green and blue or red, green, blue and white. A red pixel, a green pixel and a blue pixel can be gathered or a red pixel, a green pixel, a blue pixel and a white pixel can be gathered to form one unit pixel. For example, each of the pixels representing each color can be called as a ‘sub-pixel’, and it can be explained that these ‘sub-pixels’form one ‘pixel’. As another example, it can be explained that pixels P representing each color are called as ‘pixels’, and three or four of these ‘pixels’are gathered to form one ‘unit pixel’. Hereinafter, the latter case will be described.

The non-display area NDA, which is an area not representing the video images, can be defined at the circumference areas of the substrate 110 surrounding all or some of the display area AA.

The gate driver 200 can supply the scan (or gate) signals to the scan lines SL according to the gate control signal received from the timing controller 500 through the pad portion 300. The gate driver 200 can be formed at the non-display area NDA at any one outside of the display area AA on the substrate 110, as a GIP (Gate driver In Panel) type. A GIP type can mean that the gate driver 200 is directly formed on the substrate 110. For example, the gate driver 200 can be configured with shift registers. In the GIP type, the transistors for shift registers of the gate driver 200 are directly formed on the upper surface of the substrate 110.

The pad portion 300 can be disposed in the non-display area NDA at one side edge of the display area AA of the substrate 110. The pad portion 300 can include data pads connected to each of the data lines DL, driving current pads connected to the driving current lines, a high-potential pad receiving a high potential voltage, and a low-potential pad receiving a low potential voltage.

The source driving IC 410 can receive the digital video data and the source control signal from the timing controller 500. The source driving IC 410 can convert the digital video data into the analog data voltages according to the source control signal and then supply that to the data lines. When the source driving IC 410 is made as a chip type, it can be mounted on the substrate 110 between display area AA and pad portion 300 as a COF (Chip On Film) or COP (Chip On Plastic) type. For another example, the source driving IC 410 can be mounted on the flexible circuit film 430.

The flexible circuit film 430 can include a plurality of link lines connecting the pad portion 300 to the circuit board 450. The flexible circuit film 430 can be attached on the pad portion 300 using an anisotropic conducting film, so that the pad portion 300 can be connected to the link lines of the flexible circuit film 430.

The circuit board 450 can be attached to the flexible circuit film 430. The circuit board 450 can include a plurality of circuits implemented as the driving chips. For example, the circuit board 450 can be a printed circuit board or a flexible printed circuit board.

The timing controller 500 can receive the digital video data and the timing signal from an external system board through the line cables of the circuit board 450. The timing controller 500 can generate a gate control signal for controlling the operation timing of the gate driver 200 and a source control signal for controlling the source driving IC 410, based on the timing signal. The timing controller 500 can supply the gate control signal to the gate driver 200 and supply the source control signal to the source driving IC 410. Depending on the product types, the timing controller 500 can be integrated with the source driving IC 410 into one driving chip and can be mounted on the substrate 110 to be connected to the pad portion 300.

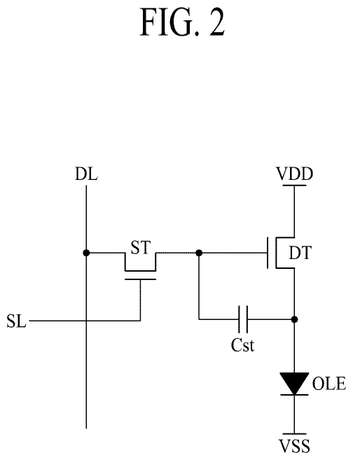

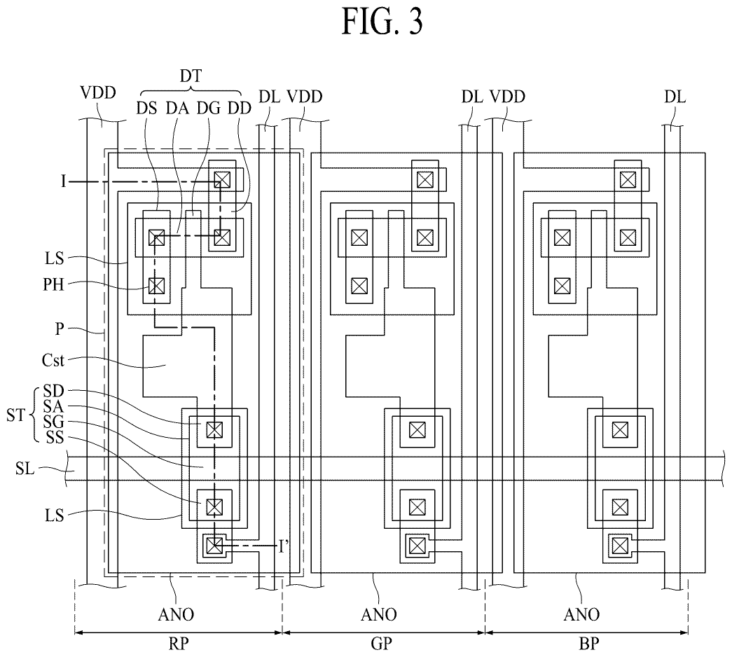

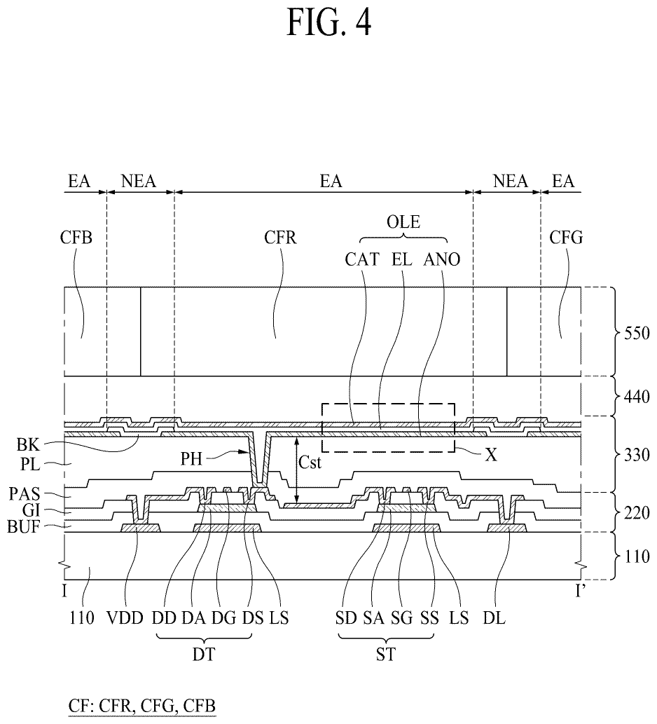

Hereinafter, referring to FIGS. 2 to 4, a detailed structure of a light emitting display device according to an embodiment of the present disclosure will be explained. FIG. 2 is a circuit diagram illustrating a structure of one pixel disposed in a light emitting display device according to an embodiment of the present disclosure. FIG. 3 is an enlarged plan view illustrating a structure of three pixels sequentially disposed in the light emitting display device according to an embodiment of the present disclosure. FIG. 4 is a cross-sectional view, cutting along line I-I′ in FIG. 3, for illustrating a structure of one pixel in a light emitting display device according to an embodiment of the present disclosure.

Referring to FIGS. 2 and 3, each pixel P of the light emitting display device according to the present disclosure can be defined by a scan line SL, a data line DL and a driving current line VDD. Each pixel P of the light emitting display device can include a switching thin film transistor ST, a driving thin film transistor DT, a light emitting diode OLE and a storage capacitance (or capacitor) Cst. The driving current line VDD can be supplied with a high-level voltage for driving the light emitting diode OLE.

In the following description referring to FIG. 3, the data line DL can be disposed at the right side of the pixel P and the driving current line VDD can be disposed at the left side of the pixel P. However, it is not limited thereto, the structure can be varied. For an example, a reference line can be disposed at the left side of a unit pixel comprising three pixels P, and driving current line can be disposed at the right side of the unit pixel. Further, each of the data line DL can be disposed at the right side of each pixel P.

Hereinafter, a top emission type light emitting display device would be described as an example. However, the light emitting display device according to the present disclosure is not limited thereto, and can be other types of light emitting display device, for example, a bottom emission type light emitting display device. A switching thin film transistor ST and a driving thin film transistor DT can be formed on a substrate 110. For example, the switching thin film transistor ST can be configured to be connected to the scan line SL and the data line DL crossing with the scan line SL. The switching thin film transistor ST can include a gate electrode SG, a semiconductor layer SA, a source electrode SS and a drain electrode SD. The gate electrode SG can be a portion of the scan line SL. The semiconductor layer SA can be disposed to overlapped with the gate electrode SG. The overlapped portion of the semiconductor layer SA with the gate electrode SG can be defined as the channel area. The source electrode SS can be branched from or connected to the data line DL, and the drain electrode SD can be connected to the driving thin film transistor DT. The source electrode SS can be connected to one side of the semiconductor layer SA with respect to the channel area, and the drain electrode SD can be connected to the other side of the semiconductor layer SA with respect to the channel area. By supplying the data signal to the driving thin film transistor DT, the switching thin film transistor ST can play a role of selecting a pixel P which would be driven.

The driving thin film transistor DT can play a role of driving the light emitting diode OLE of the selected pixel P by the switching thin film transistor ST. The driving thin film transistor DT can include a gate electrode DG, a semiconductor layer DA, a source electrode DS and a drain electrode DD. The gate electrode DG of the driving thin film transistor DT can be connected to the drain electrode SD of the switching thin film transistor ST. For example, the gate electrode DG of the driving thin film transistor DT can be extended from the drain electrode SD of the switching thin film transistor ST. In the driving thin film transistor DT, the drain electrode DD can be branched from or connected to the driving current line VDD, further, the source electrode DS can be connected to the anode electrode (or pixel electrode) ANO of the light emitting diode (or light emitting element) OLE. The semiconductor layer DA can be disposed to overlapped with the gate electrode DG. In the semiconductor layer DA, the overlapped portion with the gate electrode DG can be defined as a channel area. The source electrode DS can be connected to one side of the semiconductor layer DA with respect to the channel area, and the drain electrode DD can be connected to the other side of the semiconductor layer DA with respect to the channel area. A storage capacitance (or, capacitor) Cst can be disposed between the gate electrode DG of the driving thin film transistor DT and the first electrode (for example, the anode electrode ANO) of the light emitting diode OLE.

The light emitting diode OLE can generate light according to the current controlled by the driving thin film transistor DT. The driving thin film transistor DT can control the amount of current flowing from the driving current line VDD to the light emitting diode OLE according to the voltage difference between the gate electrode DG and the source electrode DS.

The light emitting diode OLE can include a firs electrode (for example, an anode electrode ANO), an emission layer EL, and a second electrode (for example, a cathode electrode CAT). The light emitting diode OLE can emit lights according to the current controlled by the driving thin film transistor DT. In other words, the light emitting diode OLE can provide an image by emitting light according to the current controlled by the driving thin film transistor DT. The anode electrode ANO of the light emitting diode OLE can be connected to the source electrode DS of the driving thin film transistor DT. The cathode electrode CAT (or, common electrode) can be connected to a low power line VSS supplied with the low-potential voltage. Therefore, the light emitting diode OLE can be driven by the electric current flown from the driving current line VDD to the low power line VSS controlled by the driving thin film transistor DT.

A plurality of pixels P can be arrayed on the substrate 110. For example, along the horizontal direction, a red pixel RP, a green pixel GP and a blue pixel BP can be sequentially arrayed and disposed. The combination of the red pixel RP, the green pixel GP and the blue pixel BP can configure one pixel. In another case, the red pixel, the green pixel, the white pixel and the blue pixel can be sequentially arrayed along the horizontal direction. The red pixel, the green pixel, the white pixel and the blue pixel can form a unit pixel. FIG. 3 shows that three pixels P, including a red pixel RP, a green pixel GP and a blue pixel BP, sequentially are arrayed along the horizontal direction.

Referring to FIG. 4, a cross-sectional structure of the light emitting display device according to an embodiment of the present disclosure will be explained. A light emitting display device can include a substrate 110, a driving element layer 220, and a light emitting element layer 330. The driving element layer 220 can include a plurality of thin layers formed on the substrate 110. The driving element layer 220 can include a switching thin film transistor ST and a driving thin film transistor DT.

On the substrate 110, a data line DL, a driving current line VDD and a light shielding layer LS can be formed. The light shielding layer LS can be disposed in an island shape spaced apart from the data line DL and the driving current line VDD by a predetermined distance and overlapping the semiconductor layers SA and DA.

A buffer layer BUF is deposited on entire surface of the substrate 110 as covering the data line DL and the driving current line VDD. On the buffer layer BUF, the semiconductor layer SA of the switching thin film transistor ST and the semiconductor layer DA of the driving thin film transistor DT are formed. The switching thin film transistor ST and the driving thin film transistor DT are formed on the buffer layer BUF. It is preferable that the channel areas in the semiconductor layers SA and DA overlap with the light shielding layer LS.

A gate insulating layer GI is deposited on the substrate 110 as covering the semiconductor layers SA and DA. A gate electrode SG overlapping with the semiconductor layer SA of the switching thin film transistor ST and the gate electrode DG overlapping with the semiconductor layer DA of the driving thin film transistor DT are formed on the gate insulating layer GI. In addition, at both sides of the gate electrode SG of the switching thin film transistor ST, a source electrode SS contacting one side of the semiconductor layer SA while being spaced apart from the gate electrode SG, and a drain electrode SD contacting the other side of the semiconductor layer SA are formed. Further, at both sides of the gate electrode DG of the driving thin film transistor DT, a source electrode DS contacting one side of the semiconductor layer DA while being spaced apart from the gate electrode DG, and a drain electrode DD contacting the other side of the semiconductor layer DA are formed.

The gate electrodes SG and DG, the source electrodes SS and DS, and the drain electrodes SD and DD are formed on the same layer, but are spatially and electrically separated from each other. The source electrode SS of the switching thin film transistor ST can be connected to the data line DL via a contact hole penetrating the gate insulating layer GI. Further, the drain electrode DD of the driving thin film transistor DT can be connected to the driving current line VDD via another contact hole penetrating the gate insulating layer GI.

A passivation layer PAS is deposited on the substrate 110 as covering the thin film transistors ST and DT. The passivation layer PAS can be made of an inorganic material such as silicon oxide or silicon nitride.

The light emitting element layer 330 is formed on the driving element layer 220. The light emitting element layer 330 can include a planarization layer PL and a light emitting diode OLE. The planarization layer PL can be a layer used to flatten the uneven surface of the substrate 110 on which the thin film transistors ST and DT are formed. In order to equalize or compensate the height difference due to the uneven surface condition, the planarization layer PL can be formed of an organic material. A pixel contact hole PH can be formed at the passivation layer PAS and the planarization layer PL to expose a portion of the source electrode DS of the driving thin film transistor DT.

A first electrode, for example, an anode electrode (or, pixel electrode) ANO can be formed on the top surface of the planarization layer PL. The anode electrode ANO can be connected to the source electrode DS of the driving thin film transistor DT via a pixel contact hole PH. The first electrode can have different structures and configuring elements according to the emission type of the light emitting diode OLE. For example, in the case of a bottom emission type that provides lights in the direction to the substrate 110, it can be formed of a transparent conductive material. For another example, in the case of a top emission type that provides lights in the upward direction facing the substrate 110, it can be formed of a metal material having excellent light reflectance. Otherwise, for the case of top emission type emitting light in the upward direction facing the substrate 110, a reflective layer formed of a metal material with excellent light reflectance can be further included below or above the transparent layer formed of a transparent conductive material. For example, as for the example of the top emission type light emitting display device, the anode electrode ANO can include a metal material. Otherwise, the anode electrode ANO can include a reflective layer, and a transparent conductive layer disposed on at least one surface of the reflective layer.

For example, the anode electrode ANO can be made of a metal material such as aluminum (Al), magnesium (Mg), calcium (Ca), silver (Ag), or an alloy or combination thereof (e.g., aluminum-magnesium alloy (AlMg)). Alternatively, the anode electrode ANO can be formed of a multilayered structure of a transparent conductive material such as indium-tin-oxide (ITO) and metal material such as silver (Ag), for example ITO/Ag/ITO.

A bank BK is formed on the top surface of the substrate 110 having the anode electrode ANO. The bank BK is preferably an insulating layer made of an inorganic material or an organic material. Hereinafter, a case made of an in organic material will be described. The bank BK covers the circumferential areas of the anode electrode ANO, and exposes most of the middle area. The middle area exposed from the bank BK is defined as an emission area EA, and the area covered by bank BK is defined as a non-emission area NEA.

An emission layer EL is disposed on the anode electrode ANO and bank BK. The emission layer EL can be deposited on entire of the display area AA of the substrate 110 as covering the anode electrode ANO and the bank BK. For an example, the emission layer EL can have a tandem structure in which a first emission part and a second emission part are vertically stacked for generating white light. However, it is not limited thereto, the vertically stacked emission layer EL can included three or four emission parts.

For another example, the emission layer EL can include any one of a blue emission part, a green emission part, and a red emission part for generating light corresponding to a color set in each pixel. Further, the light emitting diode OLE can include a functional layer for improving light emitting efficiency and/or lifetime of the emission layer EL.

A cathode electrode (or common electrode) CAT is deposited on the entire surface of the substrate 110 on which the emission layer is formed. The cathode electrode CAT is deposited to make surface contact with the emission layer EL. The cathode electrode CAT is formed over the entire substrate 110 to be commonly connected to the emission layer EL deposited in all pixels. In the case of the top emission type, the cathode electrode CAT can include a transparent conductive material. For example, the cathode electrode CAT can be made of a transparent conductive material such as indium-tin-oxide (ITO) or indium-zinc-oxide (IZO).

An encapsulation layer 440 is stacked on the light emitting element layer 330. The encapsulation layer 440 can have a single-layer structure made of an inorganic material, or a multi-layer structure in which several inorganic layers are sequentially stacked. As another example, the encapsulation layer 440 can have a structure in which an inorganic layer, an organic layer and an inorganic layer are continuously stacked. Here, for convenience of description, the encapsulation layer 440 made of a single inorganic layer will be used for explanation.

A color filter layer 550 is stacked on the encapsulation layer 440. In the color filter layer 550, a plurality of color filters CF can be arranged in a matrix manner to correspond to the arrangement of the pixels P. For example, any one of red color filter CFR, green color filter CFG and blue color filter CFB can be allocated at each pixel P. As another example, the color filter CF can be disposed with a structure in which one of a red color filter, a white color filter, a green color filter and a blue color filter is allocated to each pixel P. Hereinafter, for convenience of description, a case, in which the color filter CF includes a red color filter CFR, a green color filter CFG and a blue color filter CFB, is used for explanation.

In the following explanation, a detailed description of the driving element layer, which is a common element, may not be duplicated. The structure of the driving element layer is not limited to the description explained referring to FIGS. 2 to 4. The thin film transistor ST and DT can be any one of a top-gate structure, a bottom gate structure and a double gate structure.

Further, the thin film transistor ST and DT can include oxide semiconductor material. For example, the semiconductor layer SA and DA can include a metal oxide material such as indium-gallium-zinc-oxide (IGZO). However, it is not limited thereto, the semiconductor layer SA and DA can include any one of an amorphous silicon (a-Si) material, a polysilicon (Poly-Si) material and a low temperature poly silicon (LTPS) material.

### First Embodiment

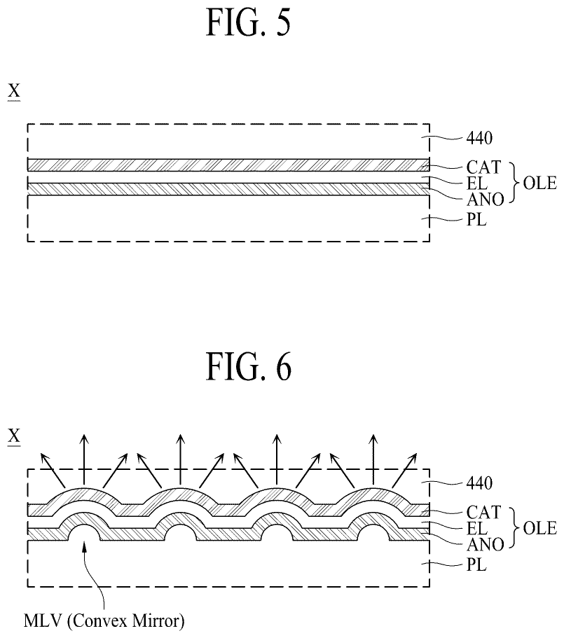

Hereinafter, a structure of a light emitting diode included in the light emitting display device according to a first embodiment of the present disclosure will be explained. The light emitting diode in the light emitting display device according to the present disclosure can include a micro mirror structure (or a mirror structure) for enhancing the front luminance and/or viewing angle luminance. Hereinafter, referring to FIG. 5, the first embodiment will be explained. FIG. 5 is a cross-sectional view, enlarging the dotted box ‘X’ of FIG. 4, for illustrating a structure of a light emitting display device according to the first embodiment of the present disclosure.

Referring to FIG. 5, a light emitting diode OLE can be formed on the planarization layer PL. An encapsulation layer 440 can be disposed on the light emitting diode OLE. The light emitting diode OLE can have a structure in which an anode electrode ANO, an emission layer EL and a cathode electrode CAT can be sequentially stacked. The light emitting diode formed in the light emitting display device shown in FIG. 5 may not include mirror structure. For example, the light emitting display device according to the first embodiment can include only flat portion in which a plurality of light emitting diodes OLE can be arranged. The structure shown in FIG. 5 can be a reference structure of a light emitting display device according to the present disclosure explained in below.

### Second Embodiment

Hereinafter, referring to FIG. 6, a structure of a light emitting display device according to a second embodiment of the present disclosure will be explained. FIG. 6 is a cross-sectional view, enlarging the dotted box ‘X’ of FIG. 4, for illustrating a structure of a light emitting display device according to the second embodiment of the present disclosure.

Referring to FIG. 6, a light emitting diode OLE can be formed on the planarization layer PL. An encapsulation layer 440 can be disposed on the light emitting diode OLE. The light emitting diode OLE can have a structure in which an anode electrode ANO, an emission layer EL and a cathode electrode CAT can be sequentially stacked.

A plurality of protrusions (or protruding structures) with a hemispherical shape protruding upward can be formed in the planarization layer PL. The protruding structures can be formed by depositing and then patterning a planarization layer PL. For another example, the protruding structures can be formed after depositing an additional insulating layer on top of the planarization layer PL, and then patterning the insulating layer. The protruding structures can have a height protruded from the planarization layer PL, and can have a hemispherical shape. However, it is not limited thereto, the protruding structures can have other shape, for example, a hemi-ellipsoidal shape, or shapes having a polygon cross-section. In addition, for example, the size of the protruding structures can be several micrometers.

Due to the protruding structures formed at the planarization layer PL, the anode electrode deposited thereon can also have a plurality of convex structures (or convex surface). Since the anode electrode ANO can be made of a metal material and that can reflect light emitted from the emission layer EL upward, the convex structures formed in the anode electrode ANO can be a mirror or a mirror structure. Since the convex structures formed in the anode electrode ANO can protrude upward, these convex structures can be named as convex micro-mirrors (or convex mirrors) MLV. A plurality of convex micro-mirrors MLV can be continuously disposed. However, it is not limited thereto, as shown in FIG. 6, a flat surface can be disposed between neighboring convex micro-mirrors MLV.

An emission layer EL can be deposited on the anode electrode ANO having a plurality of convex micro-mirrors MLV. Since the emission layer EL can be deposited along the profile of the convex micro-mirrors MLV, the emission layer EL can also have a convex structure. A cathode electrode CAT can be deposited on the emission layer EL having the convex structure. Since the cathode electrode CAT can be deposited along the profile of the convex micro-mirrors MLV, the cathode electrode CAT can also have a convex structure.

Due to the protruding structure formed at the planarization layer PL, the anode electrode ANO the light emitting diode OLE can have a structure in which a plurality of convex micro-mirrors MLVs are dispersed. Further, since the emission layer EL can be deposited while covering a plurality of convex micro-mirrors MLV, the surface area of the emission layer EL according to the second embodiment can be larger than that of the emission layer EL according to the first embodiment, even though the pixel sizes are the same. Therefore, the second embodiment can provide a structure in which the light efficiency of light emitted from a single pixel can be improved even though in a light emitting display device having a small pixel size.

Further, the emission layer EL deposited on the top surface of the convex micro-mirror MLV can provide light being spread in a fan-shaped direction, as shown by the arrow in FIG. 6. Therefore, it can provide more light in the viewing angle direction. As a result, the second embodiment can provide a light emitting display device with improved viewing angle luminance (or brightness).

### Third Embodiment

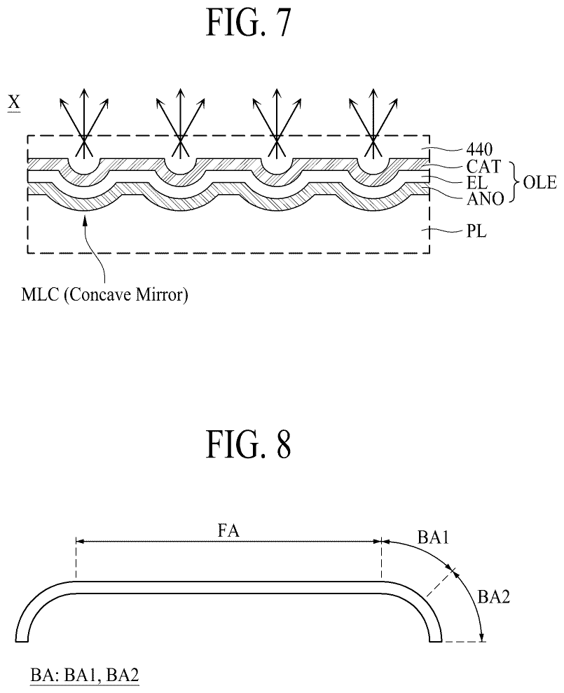

Hereinafter, referring to FIG. 7, a structure of a light emitting display device according to a third embodiment of the present disclosure will be explained. FIG. 7 is a cross-sectional view, enlarging the dotted box ‘X’ of FIG. 4, for illustrating a structure of a light emitting display device according to the third embodiment of the present disclosure.

Referring to FIG. 7, a light emitting diode OLE can be formed on the planarization layer PL. An encapsulation layer 440 can be disposed on the light emitting diode OLE. The light emitting diode OLE can have a structure in which an anode electrode ANO, an emission layer EL and a cathode electrode CAT can be sequentially stacked.

A plurality of recesses (or recessed structures) with a hemispherical shape that are recessed downward can be formed at the planarization layer PL. The recessed structures can be formed by depositing the planarization layer PL and then patterning it. The recessed structures can have height recessed into the planarization layer PL, and can have a hemispherical shape. However, it is not limited thereto, the recessed structures can have other shape, for example, a hemi-ellipsoidal shape, or shapes having a polygon cross-section. In addition, for example, the size of the recessed structures can be several micrometers.

Due to the recessed structures formed at the planarization layer PL, the anode electrode ANO deposited thereon can also have a plurality of concave structures (or concave surfaces). Since the anode electrode ANO is made of a metal material and can reflect light emitted from the emission layer EL upward, the concave structures formed in the anode electrode ANO can be the mirror or mirror structure. Since the concave structures formed in the anode electrode ANO can be recessed downward, these concave structures can be called as a concave micro-mirror (or concave mirrors) MLC. A plurality of concave micro-mirrors MLC can be continuously disposed. However, it is not limited thereto, a flat surface can be disposed between neighboring concave micro-mirrors MLC, as shown in FIG. 7.

An emission layer EL can be deposited on the anode electrode ANO having a plurality of the concave micro-mirrors MLC. Since the emission layer EL can be deposited along the profile of the concave micro-mirrors MLC, the emission layer EL can also have the concave structure. A cathode electrode CAT can be deposited on the emission layer EL having the concave structure. Since the cathode electrode CAT can be deposited along the profile of the concave micro-mirrors MLC, the cathode electrode CAT can also have the concave structure.

Due to the recessed structure formed at the planarization layer PL, the anode electrode ANO of the light emitting diode OLE can have a structure in which a plurality of concave micro-mirrors MLC are dispersed. Further, since the emission layer EL can be deposited while covering the plurality of concave micro-mirrors MLC, the surface area of the emission layer EL according to the third embodiment can be larger than the area of the emission layer EL according to the first embodiment, even though the pixel sizes are the same. Accordingly, the third embodiment can provide a structure in which the light efficiency of light emitted from a single pixel can be improved even though in a light emitting display device having a small pixel size.

In addition, the emission layer EL deposited on a top surface of the concave micro-mirrors MLC can provide light in a direction that is converged toward the central region, as indicated by the arrow shown in FIG. 7. Therefore, it can provide more light in the front direction. As a result, the third embodiment can provide a light emitting display device with improved front luminance (or brightness).

### Fourth Embodiment

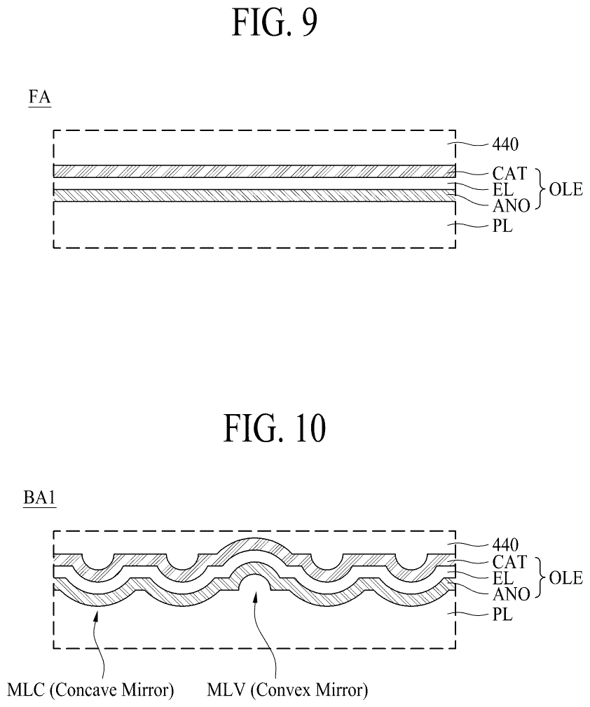

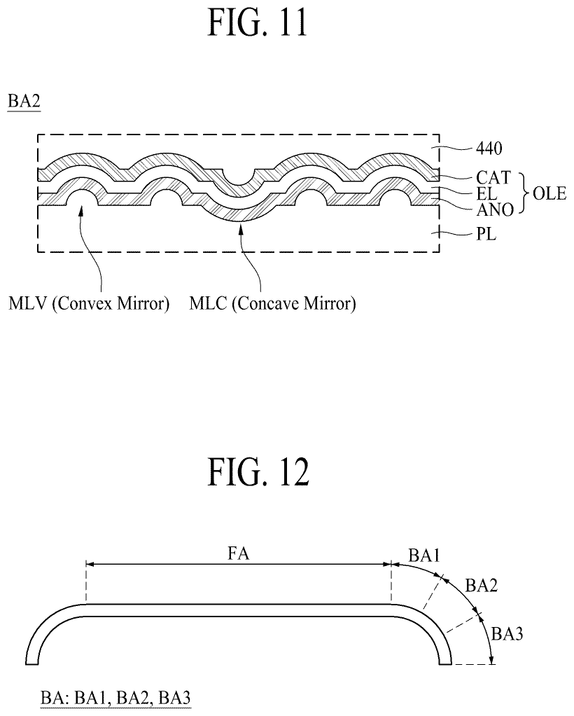

Hereinafter, referring to FIGS. 8 to 11, a structure of a light emitting display device according to a fourth embodiment of the present disclosure can be explained. FIG. 8 is a side view for illustrating a structure of a light emitting display device having a flat portion and a curved portion according to the fourth embodiment of the present disclosure. FIG. 9 is a cross-sectional view, enlarging the dotted box ‘X’ of FIG. 4, for illustrating a structure of a light emitting diode disposed in a flat portion in a light emitting display device according to the fourth embodiment of the present disclosure. FIG. 10 is a cross-sectional view, enlarging the dotted box ‘X’ of FIG. 4, for illustrating a structure of a light emitting diode disposed in a first curved portion in a light emitting display device according to the fourth embodiment of the present disclosure. FIG. 11 is a cross-sectional view, enlarging the dotted box ‘X’ of FIG. 4, for illustrating a structure of a light emitting diode disposed in a second curved portion in a light emitting display device according to the fourth embodiment of the present disclosure.

Referring to FIG. 8, the fourth embodiment of the present disclosure can provide a light emitting display device having a flat portion FA and a curved portion BA. In the related art, the display device can include a flat portion only. For an example, the light emitting display device according to present disclosure can have a structure in which the left and right sides have an edge that can be bent 90 degrees in the downward direction. However, it is not limited thereto, and it can be other bent angle, for example, 30 degrees, 45 degrees, 60 degrees. The flat portion FA can correspond to most of the central area of the light emitting display device, and the curved portion BA can correspond to the area where the left and right sides can be bent downward. In addition, the curved portion is not limited to the area where the left and right sides as shown in FIG. 8, and can be the area at one side or even at four sides. For another example, the light emitting display device can have a ‘J-type’ curved structure in which lower portion can be bent toward the observer's direction. Accordingly, for example, a substrate can include a first area and a second area, and the first area can correspond to a flat portion and the second area can correspond to a curved portion extending from the flat portion. As described above, in some embodiments, the planarization layer can include an uneven structure (for example, a protruding structure or a recessed structure) disposed on the second area, and the first electrode of at least one of the plurality of light emitting diodes can have an uneven surface (for example, a convex surface or a concave surface) corresponding to the uneven structure. Accordingly, it can provide more light in the viewing angle direction or the front direction, thereby enhancing the viewing angle luminance or the front luminance. In addition, a surface area of the emission layer (for example, it has a uneven surface) of a first light emitting diode (for example, a light emitting diode of a subpixel disposed in the curved portion) of a first subpixel can be larger than a surface area of the emission layer (for example, it has a flat surface) of a second light emitting diode (for example, a light emitting diode of a subpixel disposed in the flat portion) of a second subpixel. Accordingly, some embodiments of the present disclosure can provide a structure in which the light efficiency of light emitted from a single subpixel can be improved even though in a light emitting display device having a small pixel size.

When the light emitting display device including a flat portion FA and a curved portion BA as shown in FIG. 8 is applied to a personal information device, the user can observe the video information from the upper central portion of the flat portion FA. In this case, the video information provided at the flat portion FA can be normally observed. However, the video information from the curved portion BA can be provided in the direction of the viewing angle, so that the brightness (or luminance) can be significantly reduced and then the image quality can be distorted. In addition, such light emitting display device can also be mounted in a dash board of a vehicle or a mobile device, but is note limited thereto.

To overcome or address the above-mentioned problems and limitations, a light emitting display device according to the fourth embodiment can have a structure in which the luminance distribution can be varied in accordance with the area position. For example, as shown in FIG. 9, the light emitting diodes OLE disposed at the flat portion FA may not have any specific structural features, i.e., can have a flat layer structure.

In a case where it is necessary to further improve the frontal luminance in flat portion FA, the anode electrode ANO of the light emitting diode OLE arranged in the flat portion FA can have a structure in which a plurality of concave micro-mirrors MLC are dispersed, as shown in FIG. 7. As a result, image information provided from the flat portion FA can have enhanced frontal luminance (or brightness).

For another example, in a case where it is necessary to further improve viewing angle luminance in flat portion FA, the anode electrode ANO of the light emitting diode OLE arranged in the flat portion FA can have a structure in which a plurality of convex micro-mirrors MLV are dispersed, as shown in FIG. 6. As a result, image information provided from the flat portion FA can have enhanced viewing angle luminance.

When observing the display device from the frontal direction, the image from the curved portion BA can be observed in the direction of the viewing angle. Therefore, the anode electrode ANO of the light emitting diode OLE arranged in the curved portion BA can have a structure in which a plurality of convex micro-mirrors MLV are dispersed as shown in FIG. 6. As a result, images provided from the curved portion BA can have enhanced luminance in the viewing angle, so image quality distortion may not occur.

For another example, the main usage environment for the display device can be one in which the user primarily observes the display device from the upper direction of the curved portion BA, depending on the usage conditions. In this case, it can be necessary to enhance the viewing angle luminance of the image provided from the curved portion BA while enhancing the frontal luminance. The anode electrode ANO of the light emitting diode OLE arranged in the curved portion BA can have a structure in which a plurality of concave micro-mirrors MLC are dispersed as shown in FIG. 7.

For the light emitting diode OLE having the concave micro-mirror MLC, the frontal luminance can be enhanced while the viewing angle luminance can be also improved to some extent. For example, referring to FIG. 7, the effect of converged lights in the frontal direction is ensured, and some lights can be provided in the direction of the viewing angle. However, compared to FIG. 6, the structure according to FIG. 7 can have a slightly lower viewing angle luminance.

Further, the curved portion BA can include a first curved portion BA1 and a second curved portion BA2. For example, the first curved portion BA1 can extend from the flat portion FA and have an arch shape curved to a 45-degree angle position from the 0-degree angle position. For example, the second curved portion BA2 can extend from the first curved portion BA1 and have an arch shape that is bent to a 90-degree angle position from the 45-degree angle position. However, it is not limited thereto, in brief, a curvature of the second curved portion BA2 can be larger than that of the first curved portion BA1.

When a user observes the display device from the frontal direction of the flat portion FA, the image provided from the second curved portion BA2 can be more distorted than the image provided from the first curved portion BA1. The image provided from the first curved portion BA1 needs to ensure a certain level of frontal luminance while improving the viewing angle luminance. In this case, as shown in FIG. 10, the light emitting diode OLE arranged in the first curved portion BA1 can be equipped with both a convex micro-mirror MLV and a concave micro-mirror MLC. For example, the light emitting diodes OLE arranged in the first curved portion BA1 can include the convex micro-mirrors MLV occupying 20% to 40%, and the concave micro-mirrors MLC occupying 60% to 80%. As a result, the frontal luminance can be configured to be enhanced more than the viewing angle luminance.

The concave micro-mirror MLC can be continuously disposed. However, it is not limited thereto, a flat surface can be disposed between the concave micro-mirrors MLC, as shown in FIG. 10. For another example, concave micro-mirrors MLC and convex micro-mirrors MLV are continuously disposed. It is not limited thereto, a flat surface can be disposed between the concave micro-mirror MLC and the convex micro-mirror MLV, as shown in FIG. 10.

Meanwhile, the second curved portion BA2 needs to improve the viewing angle luminance more than the first curved portion BA1. In this case, the light emitting diodes OLE arranged in the second curved portion BA2 can include the concave micro-mirrors MLC occupying 20% to 40%, and the convex micro-mirrors MLV occupying 60% to 80%. As a result, the viewing angle luminance can be configured to be enhanced more than the frontal luminance. As described above, a ratio of the concave micro-mirrors MLC (or the concave surface) occupying in the first electrode of each of the light emitting diodes disposed in the first curved portion BA1 is greater than a ratio of the concave micro-mirrors MLC (or the concave surface) occupying in the first electrode of each of the light emitting diodes disposed in the second curved portion BA2.

The convex micro-mirrors MLV can be continuously dispersed. However, it is not limited thereto, a flat surface can be disposed between the convex micro-mirrors MLV, as shown in FIG. 11. Further, concave micro-mirrors MLC and convex micro-mirrors MLV can be continuously disposed. However, it is not limited thereto, a flat surface can be disposed between the concave micro-mirror MLC and the concave micro-mirror MLV.

For another example, in the light emitting diode OLE arranged in the first curved portion BA1, the dispersion ratio of the convex micro-mirror MLV and the concave micro-mirror MLC can be 1:6. Meanwhile, in the light emitting diode OLE arranged in the second curved portion BA2, the dispersion ratio of the convex micro-mirror MLV and the concave micro-mirror MLC can be 6:1.

In the light emitting display device having a flat portion and a curved portion according to the fourth embodiment of the present disclosure, the frontal luminance and viewing angle luminance provided at the flat portion and the curved portion can be set differently. Therefore, the image observed at the user's position can have a little difference in luminance over the entire surface of the display device, so a high quality video information without distortion can be ensured.

### Fifth Embodiment

Hereinafter, referring to FIGS. 12 to 18, a structure of a light emitting display device according to a fifth embodiment of the present disclosure will be explained. FIG. 12 is a side view for illustrating a structure of a light emitting display device having a flat portion and a curved portion according to the fifth embodiment of the present disclosure.

Referring to FIG. 12, the fifth embodiment of the present disclosure can provide a light emitting display device having a flat portion FA and a curved portion BA. The flat portion FA can be an area corresponding to middle portion of the display device, and the curved portion BA can be the areas corresponding to the left side area and the right side area bent downward.

In the light emitting display device having the flat portion FA and the curved portion BA shown in FIG. 12, the user can observe the image from the middle position of the flat portion FA. With this condition, the image quality provided from the flat portion FA can depend on the frontal luminance, so it can be normally observed by the user. Meanwhile, the image quality provided from the curved portion BA can depend on the lateral viewing angle luminance. Therefore, the luminance observed by the user can be degraded and/or the image can be distorted.

To solve or address the above-mentioned problem and limitation, the fifth embodiment can provide a light emitting display device of which luminance distribution can be set differently for each portion. The flat portion FA can have any one structure shown in FIGS. 5, 6 and 7. When the light emitting diode OLE formed on the flat portion FA has enough frontal luminance and viewing angle luminance to meet the required conditions of the display device, the light emitting diode OLE arranged in the flat portion FA can have no specific structure, i.e., can have a flat layer structure, as shown in FIG. 5. When the frontal luminance is required to be enhanced and the viewing angle luminance is required to be improved at the flat portion FA, the anode electrode ANO of the light emitting diode OLE arranged in the flat portion FA can have a structure in which a plurality of concave micro-mirrors MLC can be dispersed, as shown in FIG. 7. When it is necessary to further improve the viewing angle luminance in the flat portion FA, the anode electrode ANO of the light emitting diode OLE arranged in the flat portion FA can have a structure in which a plurality of convex micro-mirrors MLV can be dispersed, as shown in FIG. 6.

When viewing the image provided from the curved portion BA at the frontal direction, it can be an image provided in the direction of viewing angle. Accordingly, the anode electrode ANO of the light emitting diode OLE arranged in the curved portion BA can have a structure in which a plurality of convex micro-mirrors MLV and a plurality of concave micro-mirrors MVC can be dispersed, as shown in FIG. 10 or FIG. 11. As a result, the image provided from the curved portion BA can have enhanced viewing angle luminance, so the image quality observed from the frontal direction may not be distorted.

In addition, for display devices in which the area occupied by the curved portion BA is larger, it can be necessary to further subdivide the curved portion BA to adjust the viewing angle luminance and frontal luminance. For example, the curved portion BA can include a first curved portion BA1, a second curved portion BA2 and a third curved portion BA3, as shown in FIG. 12. For example, in some embodiments, a curvature of the second curved portion BA2 can be larger than that of the first curved portion BA1, and a curvature of the third curved portion BA3 can be larger than that of the second curved portion BA2. In addition, in some embodiments, the second curved portion BA2 can extend from the first curved portion BA1, and the third curved portion BA3 can extend from the second curved portion BA2,but it is not limited thereto, the first curved portion BA1, the second curved portion BA2 and the third curved portion BA3 can also be a certain section in the curved portion BA without a connectionship.

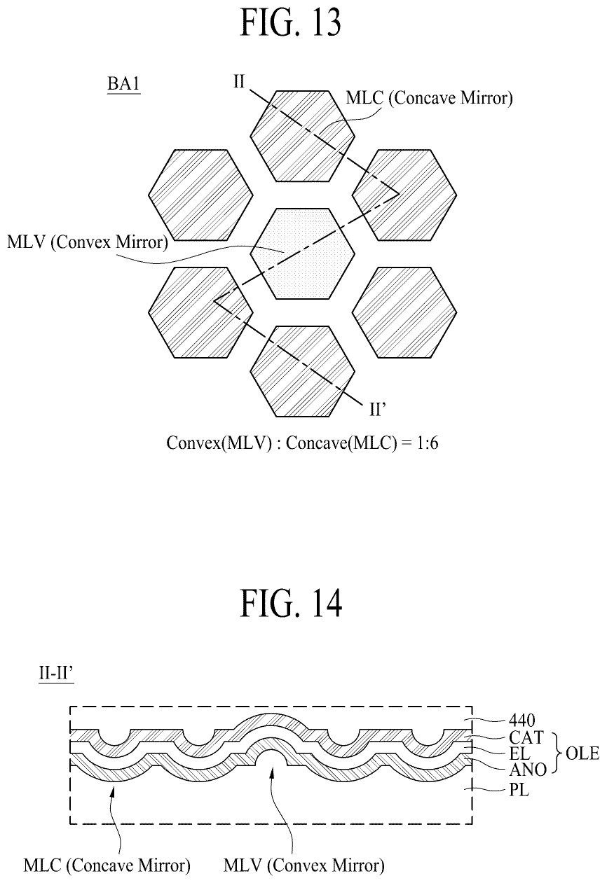

Hereinafter, referring to FIGS. 13 to 18, the detailed structures of a first curved portion BA1, a second curved portion BA2 and a third curved portion configuring the curved portion BA can be explained. To clearly compare the structures at each curved portion BA, the position of the cutting lines in the plan view for illustrating the structure of each curved portion can be arranged so as to cut the same position. In some embodiments, as shown in FIGS. 13 to 18, the convex structures (or the convex surfaces of the first electrode, the convex micro-mirrors MLV) and the concave structures (or the concave surfaces of the first electrode, the concave micro-mirrors MLC) can be arranged to form a plurality of unit patterns, each of which including a center position and six outer positions, and in each unit pattern, the convex structures (or the convex surfaces of the first electrode, the convex micro-mirrors MLV)) and the concave structures (or the concave surfaces of the first electrode, the concave micro-mirrors MLC) can be respectively disposed at the center position and the six outer positions. For example, the unit pattern can be a hexagon shape or a circle shape, but is not limited thereto.

First, referring to FIGS. 13 and 14, a structure of a first curved portion BA1 can be explained. FIG. 13 is an enlarged plan view for illustrating a distribution of convex and concave structures disposed at the light emitting diodes arranged in the first curved portion in the light emitting display device according to the fifth embodiment of the present disclosure. FIG. 14 is an enlarged cross-sectional view, cutting along line II-II′ of FIG. 13, for illustrating a distribution of convex and concave structures disposed at the light emitting diodes arranged in the first curved portion in the light emitting display device according to the fifth embodiment of the present disclosure.

In the first curved portion BA1, it is required to enhance the frontal luminance can be enhanced, and the viewing angle luminance can be improved to some extent. Since the first curved portion BA1 is adjacent to the flat portion FA and has a degree of curvature that is not greater than that of the other curved portions BA2 and BA3, it is required to ensure the frontal luminance while also enhancing viewing angle luminance. In this case, the anode electrode ANO of the light emitting diode OLE arranged in the first curved portion BA1 can include convex micro-mirrors MLV and concave micro-mirrors MLC so as to have a distribution structure as shown in FIG. 13. For example, in some embodiments, in each unit pattern in the first curved portion BA1, one convex structure can be disposed at the center position, and six concave structures can be respectively disposed at the six outer positions. For example, the dispersion ratio between the convex micro-mirrors MLV and the concave micro-mirrors MLC can be 1:6. FIG. 14 can have the similar or same structure as FIG. 10.

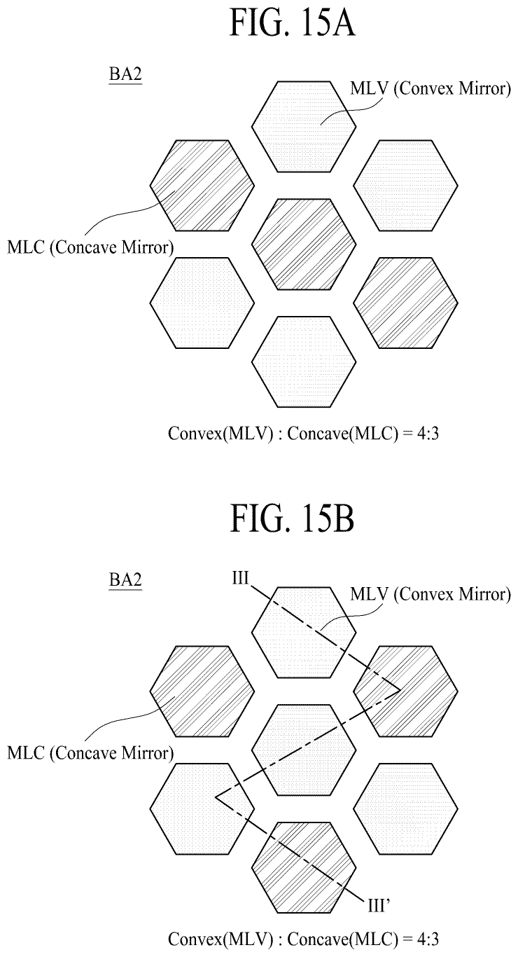

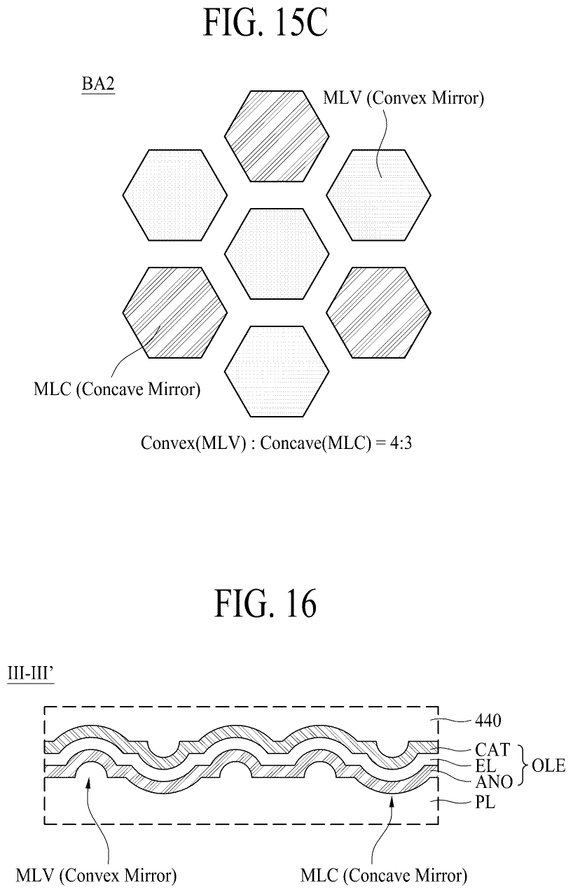

Next, referring to FIGS. 15A, 15B and 15C and FIG. 16, a structure of a second curved portion BA2 can be explained. FIGS. 15A, 15B and 15C are enlarged plan views for illustrating distributions of convex and concave structures disposed at the light emitting diodes arranged in the second curved portion in the light emitting display device according to the fifth embodiment of the present disclosure. FIG. 16 is a cross-sectional view, cutting along line III-III′ in FIG. 15B, for illustrating a distribution of convex and concave structures disposed at the light emitting diodes arranged in the second curved portion in the light emitting display device according to the fifth embodiment of the present disclosure.

The second curved portion BA2 can need to further improve the viewing angle luminance, but can also need to enhance the frontal luminance to almost the same level as the viewing angle luminance. The second curved portion BA2 needs to have more enhanced viewing angle luminance than the first curved portion BA1. For example, in the second curved portion BA2, it is preferable that the viewing angle luminance be higher than the frontal luminance. In this case, the anode electrode ANO of the light emitting diode OLE arranged in the second curved portion BA2 can include convex micro-mirrors MLV and concave micro-mirrors MLC so as to have a distributed structure such as one of FIGS. 15A to 15C. For example, the dispersion ratio between the convex micro-mirror MLV and the concave micro-mirror MLC can be 4:3. FIGS. 15A, 15B and 15C illustrate cases where the distribution ratios are the same, but the distribution manners are different. FIG. 16 shows a cross-sectional structure in which convex micro-mirror MLV and the concave micro-mirror MLC can have 4:3 distribution ratio, as in FIG. 15B. For example, in some embodiments, in each unit pattern in the second curved portion BA2, one concave structure can be disposed at the center position, and four convex structures and two concave structures spaced apart by two convex structures from each other can be respectively disposed at the six outer positions; or one convex structure can be disposed at the center position, and three concave structures and three convex structures can be alternatively disposed one by one at the six outer positions.

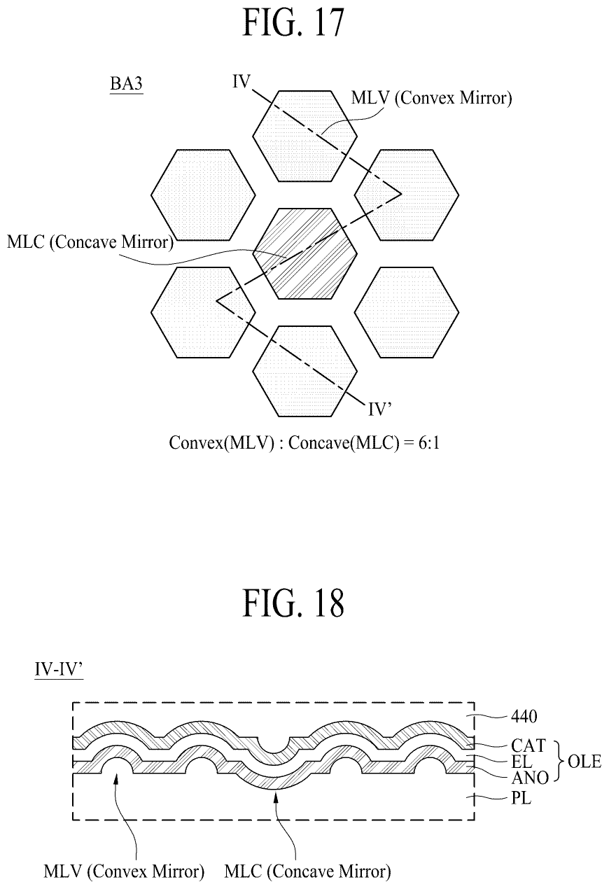

Finally, referring to FIGS. 17 and 18, a structure of a third curved portion BA3 can be explained. FIG. 17 is an enlarged plan view illustrating a distribution of convex and concave structures disposed at the light emitting diodes arranged in the third curved portion in the light emitting display device according to the fifth embodiment of the present disclosure. FIG. 18 is a cross-sectional view, cutting along line IV-IV′ in FIG. 17, for illustrating a distribution of convex and concave structures disposed at the light emitting diodes arranged in the third curved portion in the light emitting display device according to the fifth embodiment of the present disclosure.

In the third curved portion BA3, the viewing angle luminance can be ensured with highest value, but the frontal luminance can be secured with certain level. The third curved portion BA3 can be oriented almost perpendicular to the flat portion FA. Accordingly, the viewing angle luminance should be high so that the user can perceive image information from the direction of observation. In this case, the anode electrode ANO of the light emitting diode OLE in the third curved portion BA3 can include the convex micro-mirrors MLV and the concave micro-mirrors MLC so as to have a distribution structure as shown in FIG. 17. For example, the dispersion ratio between the convex micro-mirror MLV and the concave micro-mirror MLC can be 6:1. FIG. 18 can have the similar or same structure as FIG. 11. For example, in some embodiments, in each unit pattern in the third curved portion BA3, one concave structure can be disposed at the center position, and six convex structures can be respectively disposed at the six outer positions.

In the light emitting display device according to the fifth embodiment, a flat surface can be disposed between convex micro-mirrors MLV. Further, a flat surface can be disposed between the concave micro-mirrors MLC. Further, a flat surface can be disposed between the convex micro-mirror MLV and the concave micro-mirror MLC.

The light emitting display device according to the fifth embodiment can have a flat portion and a curved portion. The frontal luminance and viewing angle luminance provided from the flat portion and the curved portion can be set differently. In particular, the viewing angle luminance and frontal luminance can be set differently depending on the curved angle in the curved portion. As a result, the image provided to the user's main observation position can have excellent image quality without distortion and/or severe luminance deviation overall display area. In the fifth embodiment, as the best example, the distribution ratio of the convex micro-mirror MLV and the concave micro-mirror MLC for each curved portion is set to an integer ratio. However, it is not limited thereto, the dispersion ratio can be changed linearly and continuously as a percentage ratio depending on the position in the curved portion.

The example embodiments of the present disclosure can also be described as follow.

According to one or more embodiments of the present disclosure, a light emitting display device includes a substrate including a first area and a second area; a driving element layer on the substrate; a light emitting element layer including a planarization layer on the driving element layer and a plurality of light emitting diodes on the planarization layer, wherein the planarization layer includes an uneven structure disposed on the second area, wherein each of the plurality of light emitting diodes includes a first electrode, an emission layer and a second electrode, wherein the first electrode of at least one of the plurality of light emitting diodes has an uneven surface corresponding to the uneven structure, and wherein the uneven structure includes a protruding structure.

The uneven structure can further include a recessed structure.

The first area can correspond to a flat portion and the second area can correspond to a curved portion extending from the flat portion, and the first electrode of the light emitting diode disposed in the curved portion can include both of a convex surface and a concave surface.

The curved portion can include a first curved portion extending from the flat portion and a second curved portion extending from the first curved portion, and a curvature of the second curved portion can be larger than that of the first curved portion.

A ratio of the concave surface occupying in the first electrode of each of the light emitting diodes disposed in the first curved portion can be greater than a ratio of the concave surface occupying in the first electrode of each of the light emitting diodes disposed in the second curved portion.

The curved portion can further include a third curved portion extending from the second curved portion, and a curvature of the third curved portion can be larger than that of the second curved portion.

The convex surfaces and the concave surfaces can be arranged to form a plurality of unit patterns, each of which including a center position and six outer positions, and in each unit pattern, the convex surfaces and the concave surfaces can be respectively disposed at the center position and the six outer positions.

In each unit pattern in the first curved portion, one convex surface can be disposed at the center position, and six concave surfaces can be respectively disposed at the six outer positions.

In each unit pattern in the second curved portion, one concave surface can be disposed at the center position, and four convex surfaces and two concave surfaces spaced apart by two convex surfaces from each other can be respectively disposed at the six outer positions.

In each unit pattern in the second curved portion, one convex surface can be disposed at the center position, and three concave surfaces and three convex surfaces can be alternatively disposed one by one at the six outer positions.

In each unit pattern in the third curved portion, one concave surface can be disposed at the center position, and six convex surfaces can be respectively disposed at the six outer positions.

The uneven surface can include a convex surface and a concave surface, and a flat surface can be disposed between at least one of neighboring convex surfaces, neighboring concave surfaces, and neighboring convex surface and concave surface.

The first electrode can be made of metal material.

According to another embodiment of the present disclosure, a light emitting display device includes a substrate; a driving element layer on the substrate; and a light emitting element layer on the driving element layer and including a plurality of light emitting diodes, wherein each of the plurality of light emitting diodes includes a first electrode, an emission layer and a second electrode, and wherein among the plurality of light emitting diodes, a surface area of the emission layer of a first light emitting diode of a first subpixel is larger than a surface area of the emission layer of a second light emitting diode of a second subpixel.

The light emitting display device can have a flat portion and a curved portion, and the first light emitting diode can be disposed in the curved portion.

The first electrode of the first light emitting diode can include a convex surface and a concave surface, which reflect a light emitted from the emission layer, and the emission layer of a first light emitting diode can include a convex structure and a concave structure respectively corresponding to the convex surface and the concave surface of the first electrode.

The curved portion can include a first curved portion and a second curved portion having a curvature larger than that of the first curved portion, and a ratio of the concave surface occupying in the first electrode of the first light emitting diode disposed in the first curved portion can be greater than a ratio of the concave surface occupying in the first electrode of the first light emitting diode disposed in the second curved portion.

The convex surface and the concave surface can be arranged to form a plurality of unit patterns, each of which including a center position and six outer positions, and in each unit pattern, the convex surface and the concave surface can be respectively disposed at the center position and the six outer positions.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment can be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the disclosure and the claims, but should be construed to include all possible embodiments along with the full scope of equivalents to which such claims are entitled. Accordingly, the claims are not limited by the disclosure.

What is claimed is:

1. A light emitting display device, comprising:
a substrate including a first area and a second area;
a driving element layer on the substrate; and
a light emitting element layer including a planarization layer on the driving element layer and a plurality of light emitting diodes on the planarization layer,
wherein the planarization layer includes an uneven structure disposed on the second area,
wherein each of the plurality of light emitting diodes includes a first electrode, an emission layer and a second electrode,
wherein the first electrode of at least one of the plurality of light emitting diodes has an uneven surface corresponding to the uneven structure of the planarization layer, and
wherein the uneven structure of the planarization layer includes a protruding structure.

2. The light emitting display device of claim 1, wherein the uneven structure of the planarization layer further includes a recessed structure.

3. The light emitting display device of claim 2, wherein the first area of the substrate corresponds to a flat portion and the second area of the substrate corresponds to a curved portion extending from the flat portion, and
wherein the first electrode of the light emitting diode disposed in the curved portion includes both a convex surface and a concave surface.

4. The light emitting display device of claim 3, wherein the curved portion includes a first curved portion extending from the flat portion and a second curved portion extending from the first curved portion, and
wherein a curvature of the second curved portion is larger than a curvature of the first curved portion.

5. The light emitting display device of claim 4, wherein a ratio of the concave surface occupying in the first electrode of each of the plurality of light emitting diodes disposed in the first curved portion is greater than a ratio of the concave surface occupying in the first electrode of each of the plurality of light emitting diodes disposed in the second curved portion.

6. The light emitting display device of claim 4, wherein the curved portion further includes a third curved portion extending from the second curved portion, and
wherein a curvature of the third curved portion is larger than the curvature of the second curved portion.

7. The light emitting display device of claim 6, wherein the convex surfaces and the concave surfaces are arranged to form a plurality of unit patterns, each of the plurality of unit patterns including a center position and six outer positions, and
wherein in each of the plurality of unit patterns, the convex surfaces and the concave surfaces are respectively disposed at the center position and the six outer positions.

8. The light emitting display device of claim 7, wherein in each of the plurality of unit patterns in the first curved portion, one convex surface is disposed at the center position, and six concave surfaces are respectively disposed at the six outer positions.

9. The light emitting display device of claim 7, wherein in each of the plurality of unit patterns in the second curved portion, one concave surface is disposed at the center position, and four convex surfaces and two concave surfaces spaced apart by two convex surfaces from each other are respectively disposed at the six outer positions.

10. The light emitting display device of claim 7, wherein in each of the plurality of unit patterns in the second curved portion, one convex surface is disposed at the center position, and three concave surfaces and three convex surfaces are alternatively disposed one by one at the six outer positions.

11. The light emitting display device of claim 7, wherein in each of the plurality of unit patterns in the third curved portion, one concave surface is disposed at the center position, and six convex surfaces are respectively disposed at the six outer positions.

12. The light emitting display device of claim 1, wherein the uneven surface of the first electrode includes a convex surface and a concave surface, and
wherein a flat surface is disposed between at least one of neighboring convex surfaces, neighboring concave surfaces, and neighboring convex surface and concave surface.

13. The light emitting display device of claim 1, wherein the first electrode includes a metal material.

14. A light emitting display device, comprising:
a substrate;
a driving element layer on the substrate; and
a light emitting element layer on the driving element layer and including a plurality of light emitting diodes,
wherein each of the plurality of light emitting diodes includes a first electrode, an emission layer and a second electrode, and
wherein among the plurality of light emitting diodes, a surface area of the emission layer of a first light emitting diode of a first subpixel is larger than a surface area of the emission layer of a second light emitting diode of a second subpixel.

15. The light emitting display device of claim 14, wherein the light emitting display device has a flat portion and a curved portion, and
wherein the first light emitting diode is disposed in the curved portion.

16. The light emitting display device of claim 15, wherein the first electrode of the first light emitting diode includes a convex surface and a concave surface, which are configured to reflect a light emitted from the emission layer, and
wherein the emission layer of the first light emitting diode includes a convex structure and a concave structure respectively corresponding to the convex surface and the concave surface of the first electrode.

17. The light emitting display device of claim 16, wherein the curved portion of the light emitting display device includes a first curved portion and a second curved portion having a curvature larger than a curvature of the first curved portion.

18. The light emitting display device of claim 17, wherein a ratio of the concave surface occupying in the first electrode of the first light emitting diode disposed in the first curved portion is greater than a ratio of the concave surface occupying in the first electrode of the first light emitting diode disposed in the second curved portion.

19. The light emitting display device of claim 16, wherein the convex surface and the concave surface are arranged to form a plurality of unit patterns, each of the plurality of unit patterns including a center position and multiple outer positions, and
wherein in each of the plurality of unit patterns, the convex surface and the concave surface are respectively disposed at the center position and the multiple outer positions.
